(19) United States
(12) Patent Application Publication
(10) Pub. No.: US 2025/0123174 A1
(43) Pub. Date: Apr. 17, 2025

(54) THERMOCOUPLE LEAK DETECTION

(71) Applicant: Helios Technical Services LLC, Cave Creek, AZ (US)

(72) Inventors: Mike HALPIN, Scottsdale, AZ (US); Steven Burch, Cave Creek, AZ (US); Montgomery Groves, JR., Gilroy, CA (US)

(21) Appl. No.: 18/717,385

(22) PCT Filed: Dec. 9, 2022
(86) PCT No.: PCT/US2022/052457

§ 371 Date: Jun. 6, 2024

Related U.S. Application Data
(60) Provisional application No. 63/287,780, filed on Dec. 9, 2021.

(51) Int. Cl. G01M 3/04; G01K 7/02

(52) U.S. Cl. CPC G01M 3/04; G01K 7/02

(57) ABSTRACT

A system includes a chamber configured to receive a semiconductor wafer, a first thermocouple coupled to the chamber and wherein at least a portion of the first thermocouple is disposed within an interior volume of the chamber, a first sample hose in fluid communication with an interior volume of the first thermocouple, and a detector in fluid communication with the first sample hose. The detector is configured to analyze a gas receive from the first sample hose. In an embodiment, the first thermocouple includes an end cap including a first channel and a second channel, wherein a first thermocouple wire of the first thermocouple extends through the first channel of the end cap and the first sample hose is coupled to the second channel.

### CROSS-REFERENCE TO RELATED APPLICATIONS

This application claims priority to U.S. Provisional Patent Application No. 63/287,780 entitled “THERMOCOUPLE LEAK DETECTION” and filed on Dec. 9, 2021, the contents of which are hereby incorporated by reference.

### BACKGROUND OF THE INVENTION

### Field of the Invention

The present invention generally relates to systems and methods for leak detection and, specifically, leak detection in the thermocouples of machines and systems for the processing and manufacture of semiconductor devices.

### Background

In semiconductor device manufacturing, wafer processing often involves the formation of structures and devices over a semiconductor substrate by the controlled deposition of materials over a surface of the wafer. These processes often involve high temperatures and the deposition of material via exposure of the wafer substrate to gases having carefully controlled compositions. This requires a controlled environment and so these manufacturing steps are often performed within a reaction chamber. The chamber can be sealed during wafer processing and allows precise control over temperature and gas or vapor content within the chamber.

To provide precise temperature control, such chambers often incorporate one or more temperature sensors in the form of thermocouples. The thermocouples are positioned about the interior volume of the chamber so as to detect ambient temperature in a number of different regions of the chamber. The temperature readings can then be fed back to a control system that can adjust temperature within the reaction chamber as necessary.

To protect the thermocouples from the harsh environment of the reaction chamber, such thermocouples are often sheathed within a quartz housing. Due to the frequent thermal cycling of the thermocouple quartz housings, however, the housings can develop microscopic cracks or fractures resulting in a breach of the thermocouple sheath. If such breaches go unnoticed, contaminants can pass through the breach from an outside environment into the interior volume of the chamber. Such contaminants can then degrade or otherwise negatively affect the structures and devices being fabricated over the wafer substrate. Similarly, gases from inside the chamber can pass through the breach into the thermocouple, potentially causing damage to the thermocouple wires resulting in faulty readings or an inoperable thermocouple. Because such breaches can be very small, they can often go unnoticed for an extended period of time, resulting in poor yield of the wafers processed in that chamber.

### SUMMARY OF THE INVENTION

In some aspects, the techniques described herein relate to a system, including: a chamber configured to receive a semiconductor wafer; a first thermocouple coupled to the chamber and wherein at least a portion of the first thermocouple is disposed within an interior volume of the chamber; a first sample hose in fluid communication with an interior volume of the first thermocouple; and a detector in fluid communication with the first sample hose, the detector being configured to analyze a gas receive from the first sample hose.

In some aspects, the techniques described herein relate to a system, wherein the first thermocouple includes an end cap including a first channel and a second channel, wherein a first thermocouple wire of the first thermocouple extends through the first channel of the end cap and the first sample hose is coupled to the second channel.

In some aspects, the techniques described herein relate to a system, wherein the second channel in the end cap includes a first segment extending in parallel to the first channel and the second channel in the end cap includes a second segment extending radially away from a central axis of the end cap.

In some aspects, the techniques described herein relate to a system, further including: a second thermocouple coupled to the chamber and wherein at least a portion of the second thermocouple is disposed within the interior volume of the chamber; and a second sample hose in fluid communication with an interior volume of the second thermocouple, wherein the detector is in fluid communication with the second sample hose.

This Summary section is neither intended to be, nor should be, construed as being representative of the full extent and scope of the present disclosure. Additional benefits, features and embodiments of the present disclosure are set forth in the attached figures and in the description hereinbelow, and as described by the claims. Accordingly, it should be understood that this Summary section may not contain all of the aspects and embodiments claimed herein.

Additionally, the disclosure herein is not meant to be limiting or restrictive in any manner. Moreover, the present disclosure is intended to provide an understanding to those of ordinary skill in the art of one or more representative embodiments supporting the claims. Thus, it is important that the claims be regarded as having a scope including constructions of various features of the present disclosure insofar as they do not depart from the scope of the methods and apparatuses consistent with the present disclosure (including the originally filed claims). Moreover, the present disclosure is intended to encompass and include obvious improvements and modifications of the present disclosure.

### BRIEF DESCRIPTION OF THE FIGURES

The accompanying drawings, which are included to provide a further understanding of the invention and are incorporated in and constitute a part of this specification, illustrate embodiments of the invention and together with the description serve to explain the principles of the invention.

In the drawings:

FIG. 1 depicts an exploded view of a generally flat rectangular chamber that may be utilized in the processing of semiconductor wafers.

FIG. 2 depicts a cross-sectional view of the chamber of FIG. 1.

FIG. 3 shows a simplified drawing of a chamber (e.g., the chamber of FIG. 1) including a number of thermocouple devices configured in accordance with the present disclosure.

FIGS. 4A-4F show additional detail of an end cap in various views.

FIGS. 5A-5G show additional detail of a rotating hub assembly in various views.

FIGS. 6A-6E depict detailed drawings of various views of a central hub.

FIGS. 6F-6I depict detailed drawings of various views of an outer housing.

FIG. 7 is a simplified block diagram of a system for implementing thermocouple leak detection in accordance with the present disclosure.

FIG. 8 is a flowchart depicting a method of leak detection that may be implemented by the system of FIG. 7 in which a manifold allows selective sampling of air from all or individual thermocouples.

FIGS. 9A-9E are images depicting components of a leak detection system configured to implement the functionality of the system of FIG. 7 and as described herein.

FIGS. 10A-10E show additional detail of an end cap in a side mount configuration that may be incorporated into the present system for leak detection.

FIGS. 11A-11C show additional detail of an end cap 1118 in a side mount configuration that may be incorporated into the present system for leak detection.

### DETAILED DESCRIPTION OF THE ILLUSTRATED EMBODIMENTS

The present invention generally relates to systems and methods for leak detection and, specifically, leak detection in the thermocouples of systems and devices for the processing and manufacture of semiconductor devices.

During various steps of a semiconductor device manufacturing process devices structures are formed over a surface of wafer substrates that comprise semiconductor materials. These steps may involve the processing of the wafer substrate at precisely controlled temperatures and in specific gaseous environment. To enable precise control over such fabrication steps, wafer processing often occurs within a sealed chamber that enables precise control of the ambient temperature, gas content, and pressure. To provide precise control over ambient temperature, such chambers often incorporate one or more temperature measuring devices, such as thermocouples. Often, multiple thermocouples are positioned about the chamber so as to detect temperature in a number of different regions of the chamber.

To protect the thermocouples from the harsh environment of the reaction chamber, such thermocouples are often sheathed within quartz housings or housings or sheaths comprising other suitable materials. Over time, the housings can develop microscopic cracks or fractures resulting in a breach of the thermocouple housing. If such breaches go unnoticed, contaminants can pass through the breach from an outside environment into the interior volume of the chamber. Such contaminants can then degrade or otherwise negatively affect the structures and devices being fabricated over the wafer substrate within the chamber. Similarly, gases can leak out through the breach from the chamber, potentially fouling the thermocouple wires of the thermocouple potentially resulting in inaccurate readings or thermocouple failure.

The present system and method for leak detection is configured to detect breaches in a reaction chamber's thermocouples. Specifically, the present system sample air from a number of sample hoses that are positioned proximate to of within the interior of the housings of each thermocouple. Air samples from the sample hoses are provided to a sensor or detector device that is configured to detect concentrations of particular types of gases that may be present within the interior volume of the thermocouple housings. For specific types of gases, if the detector detects a concentration exceed a particular predetermined threshold, the detector may determine that one or more of the thermocouples housings has become breached.

During many fabrication processes, the reaction chamber may contain a relatively high concentration of hydrogen (H₂) that significantly exceeds the concentration of hydrogen found in ambient air. As such, should one of the housings of the chamber's thermocouples become breached, that hydrogen gas will tend to migrate out of the chamber and into the interior volume of the thermocouple housing through the breach. The present detection system can draw gas from the interior of the thermocouple housing (i.e., under a moderate vacuum sufficient to draw air from the interior volume of the thermocouple) toward the sensor or detector device. The detector can then be configured to generate an alarm or user-perceivable output should the detector detect a concentration of hydrogen gas that exceeds a threshold value. In this manner, the presence of a relatively high concentration of hydrogen gas within the thermocouple housing can be indicative of a breach. Hydrogen gas can be a ready indicator of thermocouple breach in that hydrogen gas disperses quickly and will rapidly migrate from the chamber into the interior of the breached thermocouple housing.

It will be apparent that during other fabrication processes in which the internal volume of the reaction chamber is filled with other types of gases, a detection system could be implemented to detect those gases instead. For example, detectors of the present disclosure may be implemented to detect nitrogen (N), hydrochloric acid (HCL) gasses or vapors, phosphene, diborane, dichlorosilane, trichlorosilane, or other types of gases that are present within a reaction chamber in measurable or detectable amounts or concentrations that exceed the typical amounts or concentrations of those gases found in ambient air.

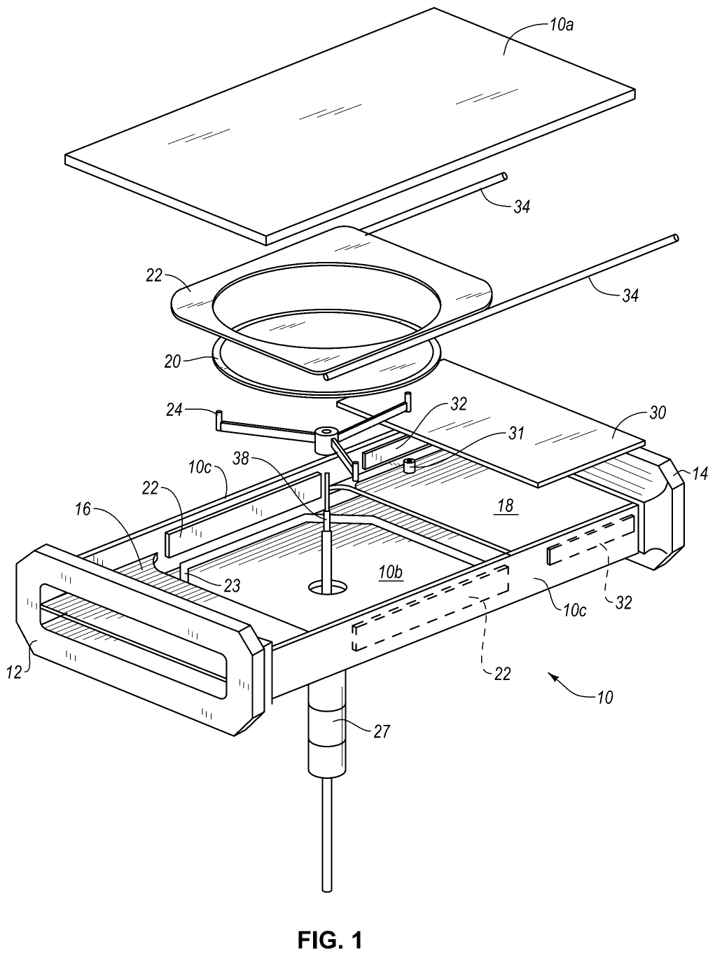

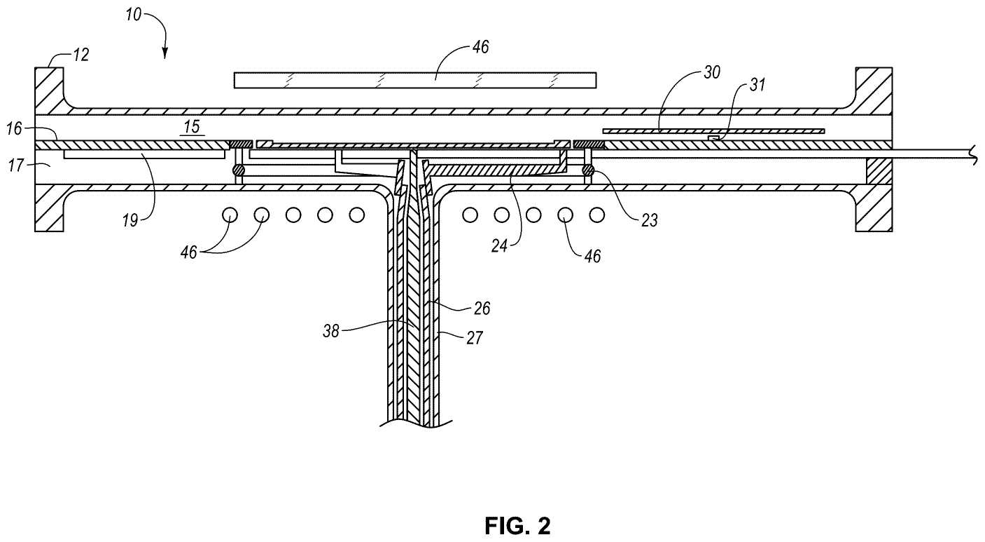

FIG. 1 depicts an exploded view of a generally flat rectangular chamber 10 that may be utilized in the processing of semiconductor wafers. In this example, chamber 10 may be configured in atmospheric chamber configuration, though it should be understood that the present invention may be utilized in conjunction with other types of reaction chambers having different configurations, such a reduced-pressure chamber. FIG. 2 depicts a cross-sectional view of chamber 10. Chamber 10 includes a flat upper wall 10a, a flat lower wall 10b joined by a pair of short vertical side walls 10c. A thickened inlet flange 12 extends across the gas inlet end of the chamber attached to the chamber walls. A similar gas outlet flange 14 is shown on the downstream end of the chamber attached to the chamber walls.

The chamber is divided into an upper section 15 and a lower section 17 by a flat front or upstream divider plate 16 and a rear, downstream plate 18 extending between the chamber side walls 10c, generally parallel to the upper and lower walls. The divider plates 16 and 18 are supported by supports 19 formed on the side walls 10c, or by supports (not shown) extending upwardly from the chamber bottom wall. The rear chamber divider plate is in approximately the same plane as the front plate. The chamber is further divided by a generally flat circular susceptor 20 and a surrounding ring 22, sometimes referred to as a temperature compensation ring or a slip ring (to prevent crystallographic slip). For best results, the thermal mass per unit irradiated area of the slip ring should be similar to that of the susceptor. Depending on the particular configuration, the optimum slip ring and thermal mass may be somewhat larger or smaller than that of the susceptor. Experimentation is suitable to identify the optimum.

The susceptor 20 is supported by a spider 24 having three arms extending radially outwardly from a central hub and having upwardly extending projections on the ends of the arms engaging the susceptor. The susceptor 20 may also be provided with one or more recesses (not shown) on its lower surface for receiving the ends of the projections so as to centrally position the susceptor and to form a coupling for rotating the susceptor. The spider is mounted on a schematically shown tubular shaft 26 which extends through the chamber lower wall 10b and also extends through a quartz tube 27 attached to and depending from the lower chamber wall. The shaft 26 is adapted to be connected to a drive (not shown) for rotating the shaft 26, the spider 24 and the susceptor 20. The ring 22 is shown supported by a stand 23 resting on the lower chamber wall 10b. Alternatively, the ring 22 may be supported on ledges extending inwardly from the chamber side walls or on ledges extending from the divider plates 16 and 18.

Positioned downstream from the susceptor 20 and the ring 22 is a getter plate 30 supported on a plurality of pins 31 extending upwardly from the rear chamber divider plate 18. The getter plate 30 extends generally parallel to and approximately mid-way between the upper chamber wall 10a and the divider plate. One or more of these plates could be used. Also optionally positioned downstream from the susceptor 20 are shields or heat absorbers 32 positioned on each side of the getter plate 30 and adjacent downstream portions of the side walls 10c. In addition, shields or heat absorbers 33 may be employed on each side of the central area of the chamber adjacent the central portions of the side walls 10c. The elements 33 may not be needed because the silicon carbide ring 22 adjacent the chamber walls may have considerable heating effect on these adjacent chamber walls. These elements 32 and 33 may be held in position by any suitable means. For example, the elements 32 might be positioned by the pins 31, and spaced slightly from the chamber side walls 10c.

To allow control over its operations, chamber 10 includes a number of thermocouples 34 and 38 configured to monitor temperatures within upper section 15 and lower section 17 of chamber 10.

Specifically, a pair of thermocouples 34 are shown on opposite sides of the ring 22, with the thermocouples 34 extending generally parallel to the chamber side walls 10c. The thermocouples 34 can be positioned beneath and supported by the ring 22. Alternatively, the thermocouples 34 may be positioned in close proximity to the slip ring, depending on the allowable temperature reading error.

Thermocouple 38 extends upwardly through the tubular shaft 26, with a tip of thermocouple 38 being located in relative proximity to the center of the susceptor 20.

In a particular chamber 10, thermocouples 34 and 38 may be of similar construction. Thermocouples 34 and 38 may include any type of thermocouple that can be configured to sensing or measuring temperatures within chamber 10 or other processing chambers of similar construction. For example, thermocouples 34 and 38 may include thermocouples spring or non-spring-mounted thermocouple junctions, or non-thermocouple-based temperature sensors in which temperature measurements are generated using a different types of temperature sensing elements.

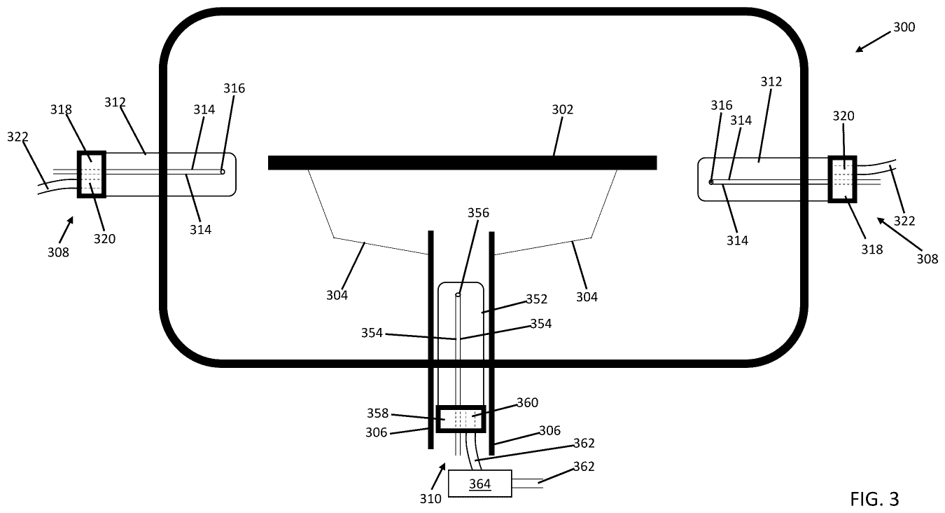

To provide further illustration, FIG. 3 shows a simplified drawing of chamber 300 (e.g., chamber 10) including a number of thermocouple devices configured in accordance with the present disclosure. Chamber 300 is simplified and so FIG. 3 does not depict all functional components of an operational chamber for the processing of semiconductor wafers.

Chamber 300 includes susceptor 302 (e.g., susceptor 20, FIGS. 1 and 2). Susceptor 302 is supported by spider 304 (e.g., spider 24, FIGS. 1 and 2). Spider 304 is mounted on a schematically shown tubular shaft 306 (e.g., shaft 26, FIGS. 1 and 2) which extends through a lower wall of chamber 300. The shaft 306 is adapted to be connected to a drive (not shown) for rotating the shaft 306, the spider 304, and the susceptor 302.

Chamber 300 includes a number of thermocouples 308 and 310 configured to monitor temperatures within Chamber 300. Specifically, FIG. 3 depicts two side thermocouples 308 positioned at opposite sides of chamber 300, and a single thermocouple 310 located within shaft 306 at a bottom of chamber 300. Although a specific configuration of thermocouples 308 and 310 is depicted in FIG. 3, it should be understood that any number of thermocouples 308 and/or 310 may be position through any side, front, back, and/or top and bottom sidewalls or surfaces of chamber 300 and extend varying distances into chamber 300 to measure temperatures at different locations within chamber 300. For example, in some embodiments of chambers for semiconductor fabrication, the chambers may include two side wall thermocouples and a single bottom thermocouple. In other embodiments, chambers may include three or four or more side thermocouples and any number of bottom and/or top thermocouples. In some embodiments, only a single thermocouple is present within chamber 300.

As shown in FIG. 3, a pair of thermocouples 308 (e.g., thermocouples 34, FIGS. 1 and 2) are shown on opposite sides of chamber 300, with the thermocouples 308 extending generally parallel through the sidewall of chamber 300. Thermocouple 310 (e.g., thermocouple 38, FIGS. 1 and 2) extends upwardly through the tubular shaft 306, with a tip of thermocouple 310 being located in relative proximity to the center of the susceptor 302.

Each thermocouple 308 includes an outer sheath 312 comprising a glass, quartz, metal, or other non-permeable material. A pair of thermocouple wires 314 extend through an end cap 318 of sheath 312 and through the interior volume of sheath 312. Thermocouple wires 314 form a junction 316 in an interior volume of sheath 312 near a tip of sheath 312. In some embodiments, thermocouples 308 may include a ceramic support or material disposed within an interior volume of sheath 312 to provide physical support and thermal insulation. In that case, thermocouple wires 314 may run through the ceramic support.

In various embodiments, each thermocouple 308 may include a plurality of junctions formed in thermocouple wires 314, where each such junction may be formed at different locations along the length of thermocouple wires 314 and/or sheath 312.

As described herein, in some embodiments a sheath 312 of a thermocouple 308 may become breached. Typically, such a breach takes the form of a microscopic crack or opening that forms in the tip or towards the tip of sheath 312 that is interior to chamber 300, though it should be understood that breaches may form in any region of the sheath 312. The breach, once formed, may allow gases from outside chamber 300 to pass through the interior volume of sheath 312, through the breach, and into the interior volume of chamber 300. Those gases may be contaminants that could degrade the quality of devices being manufactured within chamber 300, thereby negatively affecting yield from the chamber. At the same time, gases may pass from the interior of chamber 300, through the breach in the sheath 312 of thermocouples 308 and into the interior volume of sheath 312 potentially damaging thermocouple wires 314 of thermocouples 308.

In many semiconductor fabrication processes, during wafer processing the interior volume of chamber 300 may be filled with a high concentration of hydrogen gas. Because hydrogen gas is relatively mobile, in the event of a breach, the hydrogen gas may flow quickly from chamber 300 into the interior volume of sheath 312 through the breach. Consequently, detection of a concentration of hydrogen gas inside sheath 312 of thermocouples 308 that exceeds normal concentration values for ambient air can be an indicator that sheath 312 has been breached.

To facilitate detection of such a breach, therefore, the end cap 318 of thermocouples 308 includes, in addition to a sealed passageway allowing thermocouple wires 314 to pass through end cap 318, a channel 320 that is in fluid communication with the interior volume of sheath 312. A sample hose 322 is coupled to channel 320 and configured so that air from within sheath 312 can be extracted through channel 320 and sample hose 322.

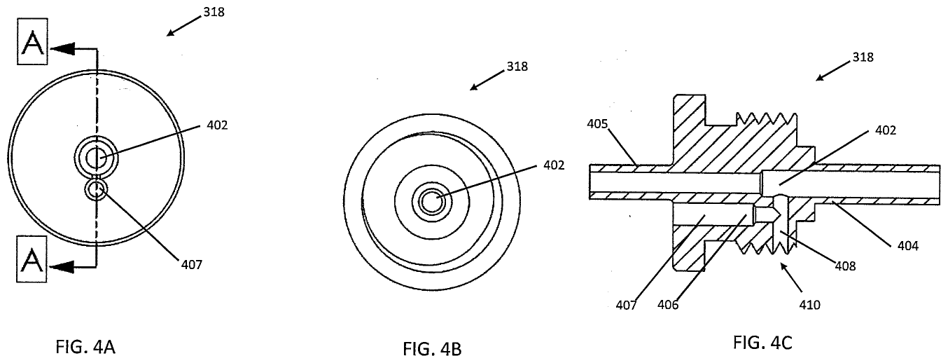

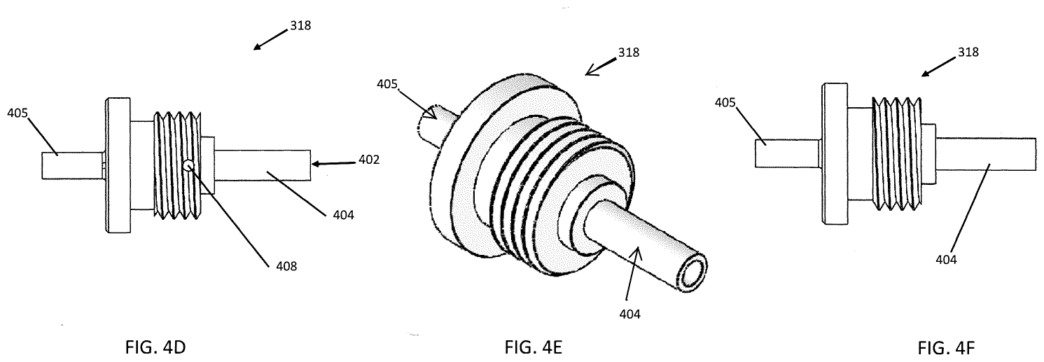

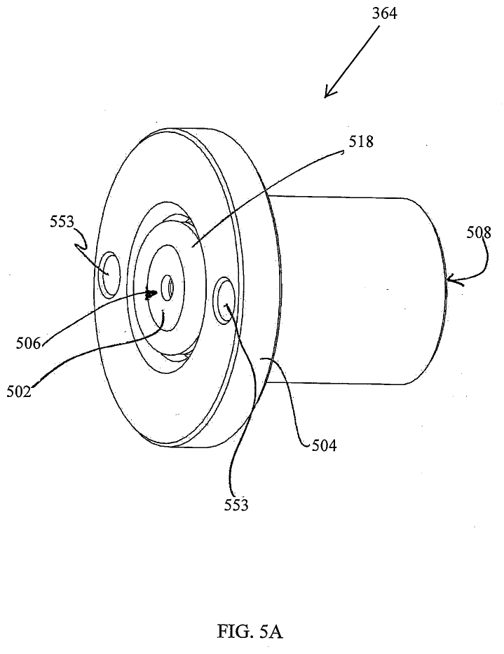

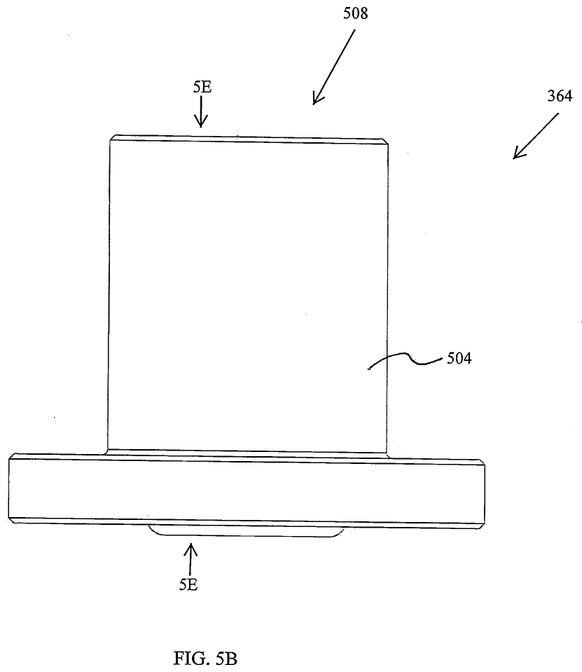

FIGS. 4A-4F show additional detail of end cap 318 in a center mount configuration in various views. FIG. 4A shows a front view and FIG. 4B a rear view of end cap 318. FIG. 4C shows a cross-sectional view of end cap 318 taken along line A-A of FIG. 4A. FIG. 4D shows a first side view of end cap 318 and FIG. 4E shows a perspective view of end cap 318. FIG. 4F shows a second side view of end cap 318.

End cap 318 includes a central channel 402 through which thermocouple wires (e.g., thermocouple wire 314, FIG. 3) may be passed. Central channel 402 may be at least partially defined by an interior central channel extension 404 and an external central channel extension 405 defined by the body of end cap 318.

End cap 318 includes channel 407 (e.g., channel 320, FIG. 3) providing a path for fluid communication through end cap 318. Specifically, channel 407 includes a first channel segment 406 that extends in parallel with central channel 402 and is laterally offset from central channel 402. In typical embodiments, first channel segment 406 of channel 407 is sized so as to be capable of receiving at least a portion of a length of a sample tube or hose (e.g., sample hose 322, FIG. 3). In other embodiment, a sample tube or hose may instead be affixed or pressed against the outside opening of channel 407 in a manner putting the sample tube or hose in fluid communication with channel 407.

As shown in FIG. 4C, in an interior of end cap 318, first channel segment 406 connects and is in fluid communication with second channel segment 408 of channel 407. Second channel segment 408 extends approximately radially away from a central axis or region of end cap 318. Second channel segment 408 forms an opening in an edge of end cap 318 at threaded portion 410 of end cap 318. Second channel segment 408 may also extend inwardly and penetrate central channel 402.

The threaded portion 410 of end cap 318 is configured to engage with a complementary barrel nut or threaded portion on the housing (e.g., housing or sheath 312) to which end cap 318 is attached to seal the housing, except for channels 402 and 407. When the threaded connection is formed between end cap 318 and a suitable housing, the opening of channel 408 in the threaded portion 410 of end cap 318 is sealed by the housing itself. In this arrangement, channel 407 is only in fluid communication with the interior volume of the connected housing via the portion of channel 408 that penetrates central channel 402.

While chamber 300 is operating, there can often be significant air turbulence in proximity to thermocouples 308. The placement and configuration of first channel segment 406 and second channel segment 408 provides that air from the internal volume of the connected thermocouple 308 is sampled through channel 407 in a region of the thermocouple housing that would experience relatively little air turbulence and also can provide that the air being sampled is not significantly diluted by ambient air. This can provide for more accurate readings and measurements pertaining to air samples from the interior volume of the thermocouple 308.

Referring to FIG. 3, central thermocouple 310 includes an outer sheath 352 comprising a glass, quartz, metal, or other non-permeable materials. A pair of thermocouple wires 354 extend through an end cap 358 of sheath 352 and through the interior volume of sheath 352 and form a junction 356 in an interior volume of sheath 352 near a tip of sheath 352. In some embodiments, thermocouple 310 may include a ceramic support or material disposed within an interior volume of sheath 352 to provide physical support and thermal insulation. In that case, thermocouple wires 354 may run through the ceramic support. In various embodiments, thermocouple 310 may include a plurality of junctions formed in thermocouple wires 354, where each such junction may be formed at different locations along the length of thermocouple wires 354 and/or sheath 352. In other embodiments, thermocouple 310 may be configured as a resistance temperature detector.

As described herein, in some circumstances a sheath 352 of thermocouple 310 may become breached. To facilitate detection of such a breach, therefore, the end cap 358 of thermocouple 310 includes, in addition to a sealed passageway allowing thermocouple wires 354 to pass through end cap 358, a channel 360 that is in fluid communication with the interior volume of sheath 352. A sample hose 362 is coupled to channel 360 and configured so that air from within sheath 352 can be extracted through channel 360 and sample hose 362.

In various embodiments, end cap 358 of thermocouple 310 may be configured in a similar manner as end cap 318 and in accordance with the design depicted in FIGS. 4A-4E.

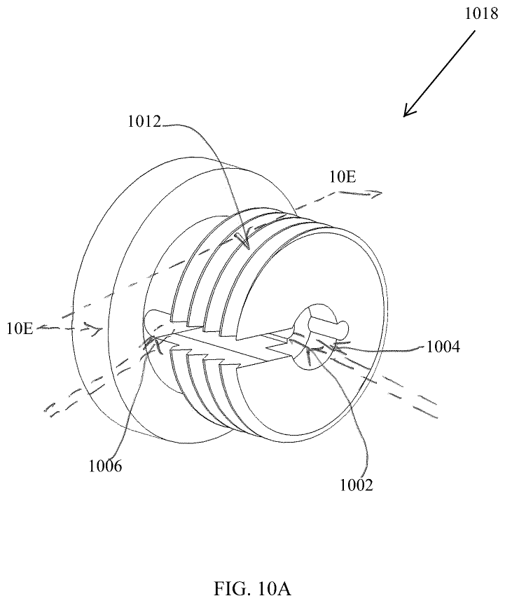

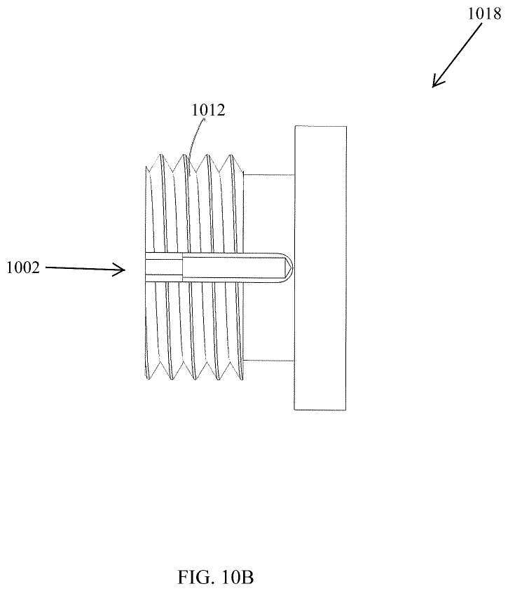

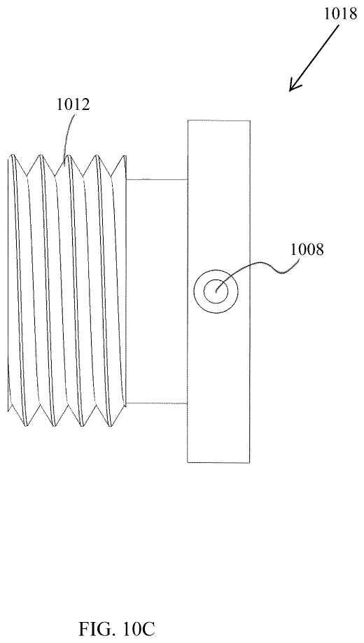

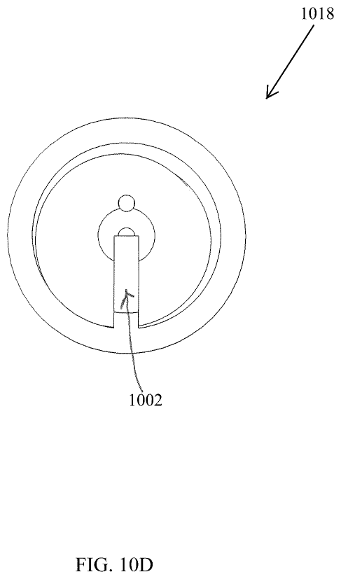

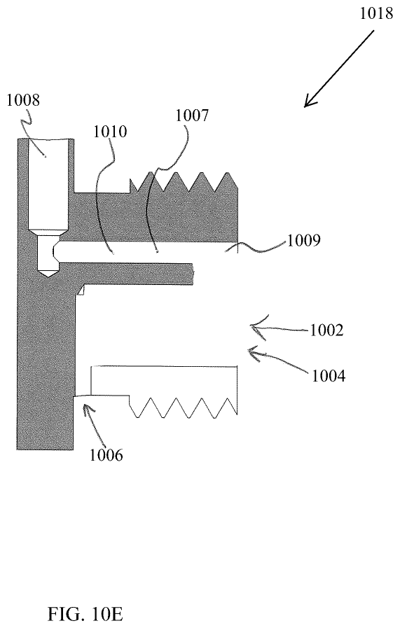

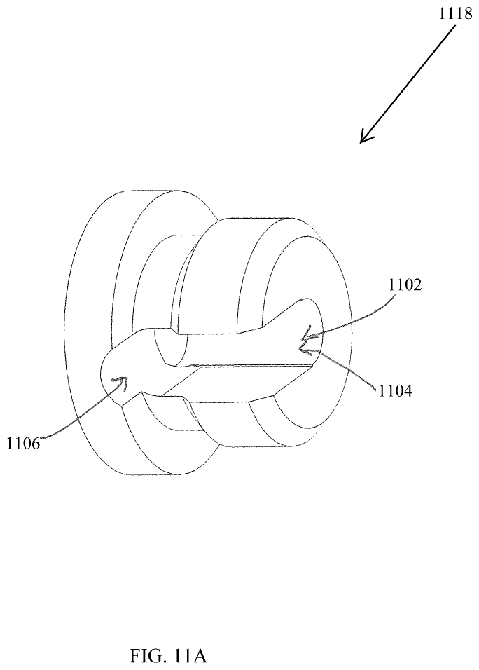

In various embodiments, end caps of different configurations may be utilized in conjunction with the present system. For example, FIGS. 10A-10E show additional detail of an end cap 1018 (e.g., end caps 318, 358) in a side mount configuration that may be incorporated into the present system for leak detection. FIG. 10A shows a perspective view of end cap 1018. FIG. 10B shows a left side view and FIG. 10C shows a right-side view of end cap 1018. FIG. 10D shows a rear view of end cap 1018. FIG. 10E shows a cross-section view of end cap 1018 taken through line 10E-10E of FIG. 10A.

The internal portion of end cap 1018 includes a central channel 1002 or opening through which thermocouple wires (e.g., thermocouple wire 314, FIG. 3) may be passed. In this configuration, with end cap 1018 attached (e.g., via threaded connection) to a thermocouple housing, the thermocouple wires may bend at an approximately 90 degree angle so that from the housing the thermocouple wire enter central channel 1002 at opening 1004 at an angle approximately parallel to an axis running along the length of the connected housing, and will exit central channel 1002 at opening 1006 at an angle that is generally perpendicular to the axis running along the length of the connected housing.

End cap 1018 includes channel 1007 (e.g., channel 320, FIG. 3) providing a path for fluid communication through end cap 1018. Specifically, channel 1007 includes a first channel segment 1008 that penetrates an external side portion of end cap 1018 and is generally sized so as to be capable of receiving at least a portion of a length of a sample tube or hose (e.g., sample hose 322, FIG. 3). In other embodiments, a sample tube or hose may instead be affixed or pressed against the outside opening of channel 1008 in a manner putting the sample tube or hose in fluid communication with channel 1008.

As shown in FIG. 10E, channel segment 1008 connects and is in fluid communication with second channel segment 1010 of channel 1007. Second channel segment 1010 extends through end cap 1018 and is in fluid communication with central channel 1002. As such, when end cap 1018 is coupled to a thermocouple housing, channel 1007 establishes a fluid connection between a sample hose coupled to channel segment 1008 and the interior volume of the thermocouple housing.

The threaded portion 1012 of end cap 1018 is configured to engage with a complementary barrel nut or threaded portion of the housing (e.g., housing or sheath 312) to which end cap 1018 is attached. The threaded connection between end cap 1018 and housing, once formed, seals the housing except for channels 1002 and 1007.

While chamber 300 is operating, there can often be significant air turbulence in proximity to thermocouples 308. The placement and configuration of channel segments 1002 and 1007 can provide that air from the internal volume of the connected thermocouple 308 is sampled through channel 1007 from a region of the thermocouple housing that would experience relatively little air turbulence and also can provide that the air being sampled is not significantly diluted by ambient air. This can provide for more accurate readings and measurement (e.g., of hydrogen concentrations (or other gases)) pertaining to air samples from the interior volume of the thermocouple 308.

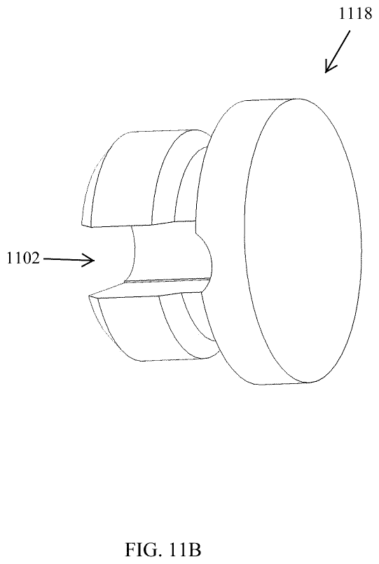

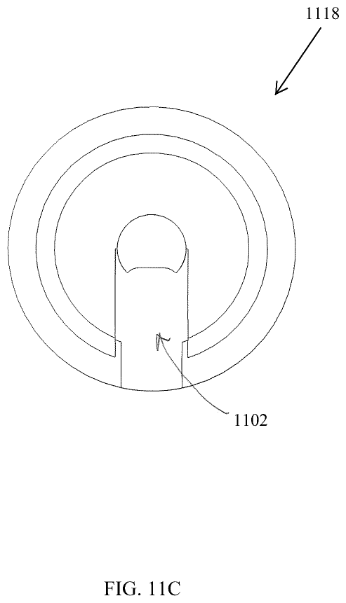

FIGS. 11A-11C show additional detail of an end cap 1118 (e.g., end caps 318, 358) in a side mount configuration that may be incorporated into the present system for leak detection. FIGS. 11A and 11B show perspective views of end cap 1118. FIG. 11C shows a rear view of end cap 1118.

End cap 1118 includes a central channel 1102 or opening through which thermocouple wires (e.g., thermocouple wire 314, FIG. 3) may be passed. In this configuration, with end cap 1118 attached (e.g., via friction connection) to a thermocouple housing, the thermocouple wires may bend at an approximately 90 degree angle so that from the housing the thermocouple wires enter central channel 1102 at an opening 1104 at an angle approximately parallel to an axis running along the length of the connected housing, and exit central channel 1102 at opening 1106 at an angle that is generally perpendicular to the axis running along the length of the connected housing. Channel 1102 is sized so that opening 1106 is sufficiently large to enable the thermocouple wires to pass through opening 1106 while also receiving at least a portion of a length of a sample tube or hose (e.g., sample hose 322, FIG. 3) at opening 1106. In other embodiments, a sample tube or hose may instead be affixed or pressed against the outside opening 1106 of channel 1102 in a manner putting the sample tube or hose in fluid communication with channel 1102.

When end cap 1118 is coupled to a thermocouple housing, channel 1102 puts the sample hose coupled to opening 1106 in fluid communication with the interior volume of the thermocouple housing.

End cap 1118 is configured to engage with the thermocouple housing via a friction fit to effectively seal the end of the thermocouple housing except for channel 1102. While chamber 300 is operating, there can often be significant air turbulence in proximity to thermocouples 308. Consequently, the placement and configuration of channel 1102 can provide that air from the internal volume of the connected thermocouple 308 is sampled through channel 1102 from a region of the thermocouple housing that would experience relatively little air turbulence and also can provide that the air being sampled is not significantly diluted by ambient air. This can provide for more accurate readings and measurement pertaining to air sample from the interior volume of the thermocouple 308.

Referring to FIG. 3, because thermocouple 310 is located within shaft 306 and because shaft 306 rotates during normal operation of chamber 300, sample hose 362 may be become twisted as chamber 300 operates. To prevent kinking or damage to sample hose 362, therefore, a rotating hub assembly 364 may be coupled in series between first and second portions of sample hose 362. Rotating hub assembly 364 is configured to enabling the first portion of sample hose 362 to rotate with respect to the second portion of sample hose 362 while maintaining the first portion in fluid communication with the second portion and an air-tight seal between the first and second portions of sample hose 362.

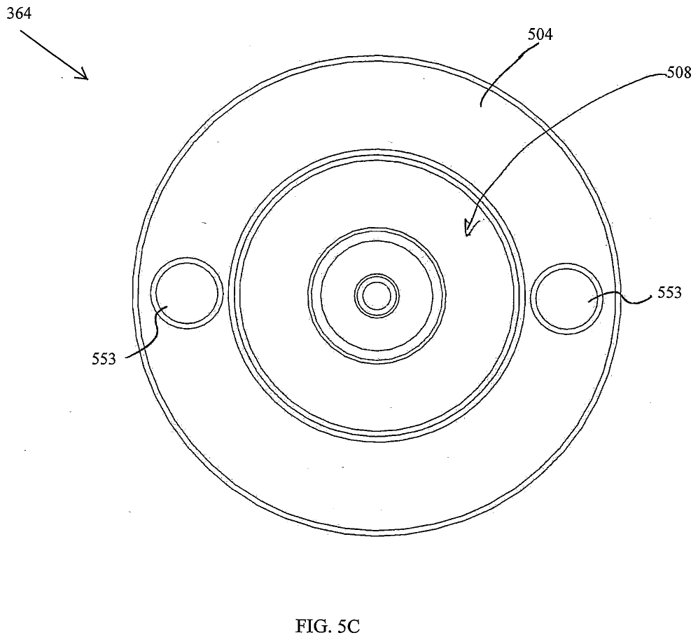

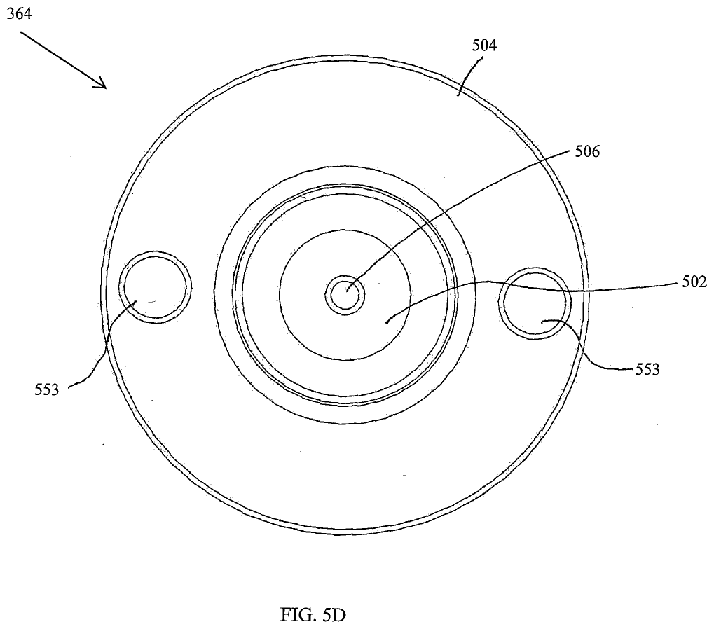

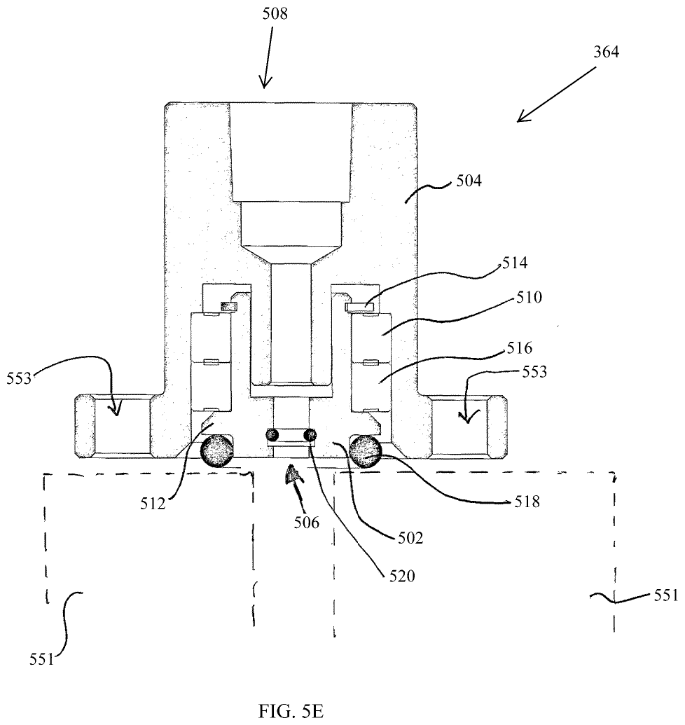

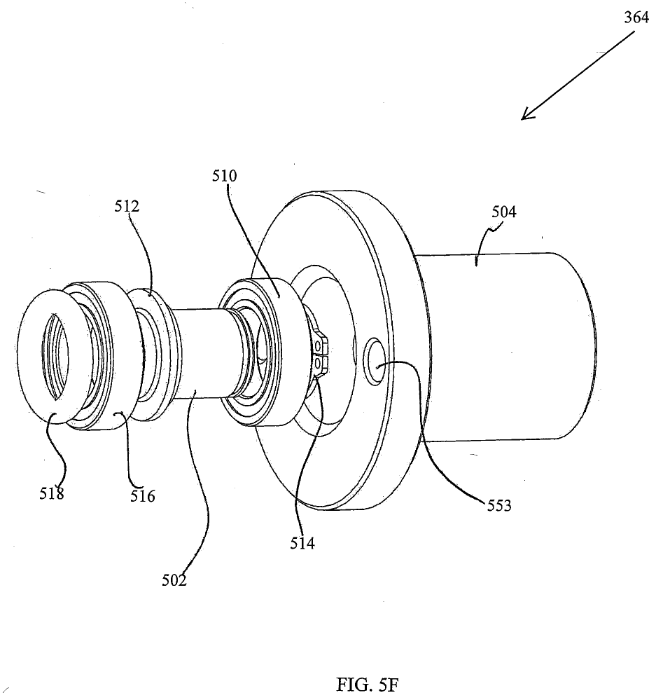

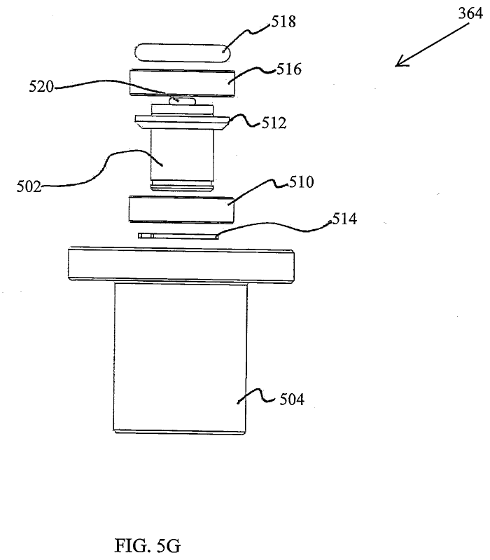

FIGS. 5A-5G show additional detail of rotating hub assembly 364 in various views. FIGS. 5A-5D show perspective, side rear, and front views of rotating hub assembly 364, respectively. FIG. 5E shows a cross-sectional view of rotating hub assembly 364 taken along line 5E-5E of FIG. 5B. FIGS. 5F and 5G depict perspective and side exploded views of rotating hub assembly 364, respectively.

Rotating hub assembly 364 includes a central hub 502 and an outer housing 504. Central hub 502 includes a port 506 configured to releasably couple to a portion of a sample hose (e.g., sample hose 362, FIG. 3) via an appropriate fitting. O-ring 520 is disposed at the perimeter of port 506 allowing for a more secure seal to be formed between port 506 and a connected sample hose. Outer housing 504 includes a port 508 configured to releasably couple to another portion of a sample hose via an appropriate fitting.

Central hub 502 is coupled to outer housing 504 via a bearing mechanism enabling central hub 502 to rotate with respect to outer housing 504 about an axis passing through the length of rotating hub assembly 364 and in a direction from port 506 to port 508. Specifically, referring to FIGS. 5E, bearings 510 and 516 are installed around the body of central hub 502 and retained against flange 512 of central hub 502 by spring clip 514. O-ring 518 is mounted against an opposing surface of flange 512, so that when rotating hub assembly 364 is mounted to a mounting surface 551 (see FIG. 5E) via mounting holes 553, O-ring 518 is sandwiched between the mounting surface 551 and flange 512 to allow central hub 502 to rotate with respect to the outer housing 504 and mounting surface 551. Mounting surface 551 may comprise a mounting plate, mounting ring, or any other suitable structure. Mounting surface 551 may be a surface that is not connected to a reaction chamber or could be a portion of a reaction chamber.

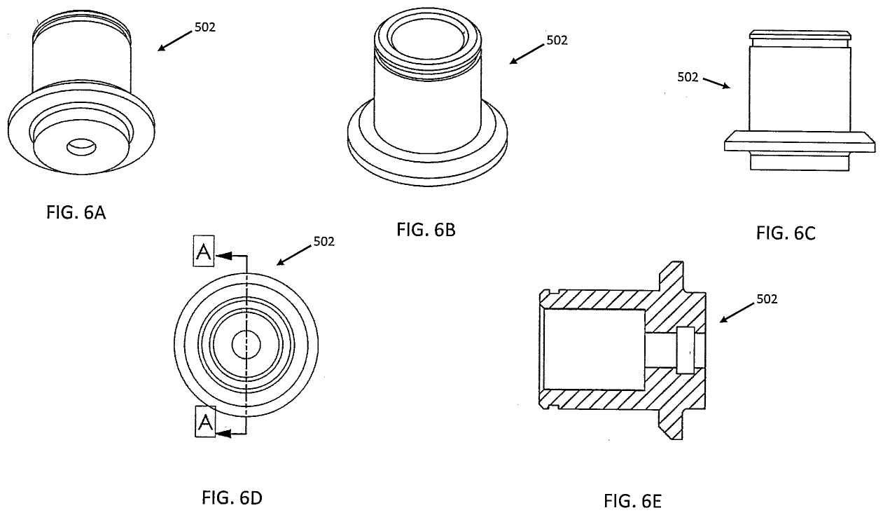

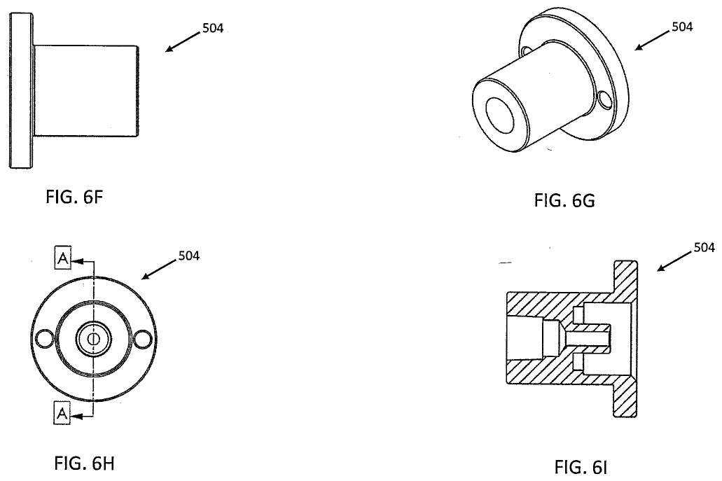

FIGS. 6A-6E depict detailed drawings of various views of central hub 502. Specifically, FIG. 6A depicts a front perspective view of central hub 502. FIG. 6B depicts a rear perspective view of central hub 502. FIG. 6C depicts a side view of central hub 502. FIG. 6D depicts a front view of central hub 502. FIG. 6E depicts a cross-sectional view of central hub 502 taken along line A-A of FIG. 6D. FIGS. 6F-6I depict detailed drawings of various views of outer housing 504. Specifically, FIG. 6F shows a side view of outer housing 504. FIG. 6G shows a rear perspective view of outer housing 504. FIG. 6H shows a front view of outer housing 504. FIG. 6I shows a cross-sectional view of outer housing 504 taken along line A-A of FIG. 6H.

Referring to FIG. 3, to provide active leak detection, the various sample hoses 322, 362 are coupled to a sensor device configured to analyze a gas content of the air or gas sampled from the interiors of the various thermocouples 308, 310. In an embodiment, that sensor device, upon detecting a quantity or concentration of a particular gas (e.g., hydrogen) in the sampled gas that exceeds typical quantities or concentrations of the surrounding ambient air, can generate an alarm indicating to a user of chamber 300 that one of its thermocouples 308, 310 may be breached.

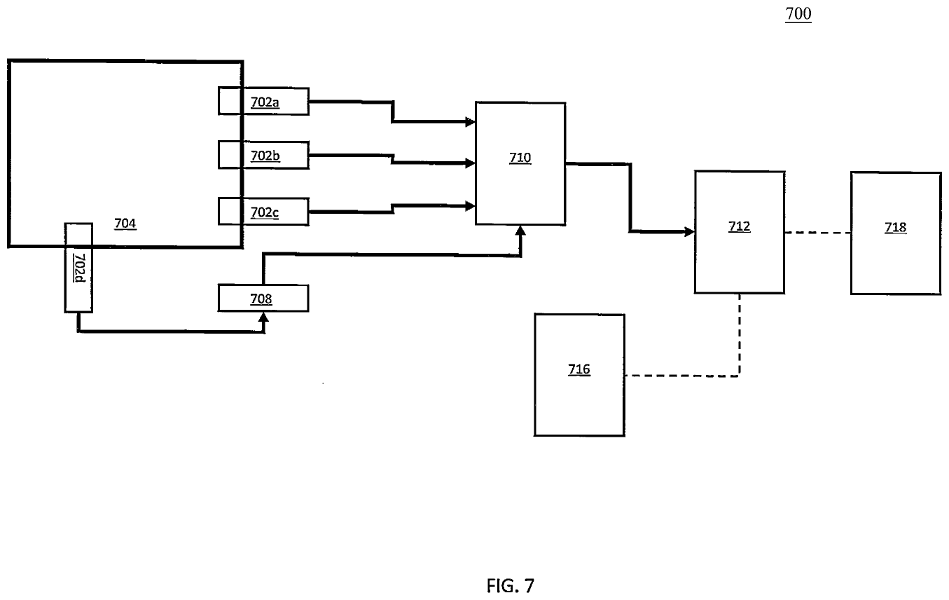

FIG. 7 is a simplified block diagram of a system 700 for implementing thermocouple leak detection in accordance with the present disclosure. As depicted, system 700 includes a number of thermocouples 702a-702d (e.g., thermocouples 308, 310, FIG. 3) that are installed within a chamber 704 (e.g., chamber 10, FIGS. 1 and 2, chamber 300, FIG. 3). Thermocouples 702 are each coupled to lengths of sample hoses 706 (e.g., sample hose 322 and/or sample hose 362, FIG. 3) that are each in fluid communication with an interior volume of the sheaths of each thermocouple 702. In some cases, some of the thermocouples 702 may be coupled to portions of chamber 704 that are configured to move or rotate. For example, in system 700, thermocouple 702d may be connected to a central rotating shaft (e.g., shaft 26 of FIGS. 1 and 2, or shaft 306 of FIG. 3) of chamber 704. As such, the sample hose 706 connected to thermocouple 702d incorporates rotating hub 708 (e.g., rotating hub assembly 364 of FIG. 3).

Sample hoses 706 are connected through manifold 710 to detector 712. In the depicted embodiment, manifold 710 includes a number of input ports configured to receive each of sample hoses 706. The input ports of manifold 710 are each in fluid communication with an output port of manifold 710. The output port of manifold 710 is connected to and in fluid communication with main hose 714 which is, in turn, connected to and in fluid communication with detector 712. In this configuration, detector 712 is configured to apply a vacuum to main hose 714. That vacuum, in turn, causes air or gas to be drawn from all sample hoses 706 simultaneously through manifold 710.

As detector 712 draws air through main hose 714, detector 712 analyzes the air to detect whether a leak is present in one or more of thermocouples 702. In a specific embodiment, detector 712 is configured to detect a concentration (e.g., in parts-per-million (PPM)) of hydrogen gas present in the air being sampled through main hose 714. If the measured PPM of hydrogen exceeds a predetermined threshold (e.g., 200 PPM), detector 712 is configured to generate an output (e.g., a low amplitude electrical signal (e.g., a milliamp signal) or an open circuit) via alarm 716 to notify a user of system 700 of a potential breach. The threshold may be static, or could change over time. For example, in some embodiments, detector 712 may be configured to measure the PPM of hydrogen in the ambient air. The threshold could then be calculated as a multiple (e.g., 1.5× or 2×) of the ambient ppm of hydrogen. This approach could allow detector 712 to adjust, over time, to variations in the ambient levels of hydrogen.

Alarm 716 may comprise a user-perceptible alarm device (e.g., audio and/or visual) implemented within detector 712 itself or connected to detector 712 that can be triggered upon determination by detector 712 that the threshold has been exceed.

In other embodiments, alarm 716 may be an output signal generated by detector 712 and communicated to the host tool in which chamber 704 is located. In that case, the signal may cause the host tool itself to generate its own alarm output. In some cases, upon receipt of the alarm signal from alarm 716, the host tool may be configured to implement any suitable risk mitigation algorithm in view of the potential breach. For example, the host tool could respond to the alarm signal by shutting down immediately. Alternatively, if wafer processing is underway, the host tool may elect to, upon receipt of the alarm signal, complete the current wafer processing process (or complete processing of the wafers in the current wafer cassette, if applicable) and then shutdown. In that case, the host tool may be configured to prevent further wafer processing until the alarm condition has been cleared. In still other cases, the host tool could simply generate the corresponding alarm output (e.g., by displaying an alarm message on a user interface device of the host tool) without changing its functional operation. The alarm signal may encode the actual measured PPM value that triggered the alarm. In that case, the host tool, upon receipt of that value, may implement an appropriate risk mitigation algorithm based upon the magnitude of the measured value.

In still other embodiments, alarm 716 may be configured to generate an electronic transmission (e.g., via a direct wired connection or via a wireless connection) enabling detector 712 to transmit a notification of the alarm event to a remote computing device, such as a laptop or desktop computer, fab monitor device, or a mobile computing device.

In other embodiments of system 700, manifold 710 may be configured to allow detector 712 to selectively draw air from one of thermocouples 702 at a time. In such a case, manifold 710 may be configured to receive a control signal from detector 712 designating a particular configuration for manifold 710 that places one or more of sample hoses 706 in fluid communication with main hose 714. The control signal may specify, for example, the sample hoses 706 for all thermocouples 702 should be placed into fluid communication with main hose 714. Alternatively, the control signal may identify a specific thermocouple 702 or combination of thermocouples 702 to cause manifold to place only the sample hoses 706 for that thermocouple 702 or combination of thermocouples 702 in fluid communication with main hose 714. In various embodiments, the thermocouples 702 in system 700 may be identified with a numeric value. For example, in a system 700 with four thermocouples 702, each thermocouple 702 may be identified by the numbers ‘1’ through ‘4’.

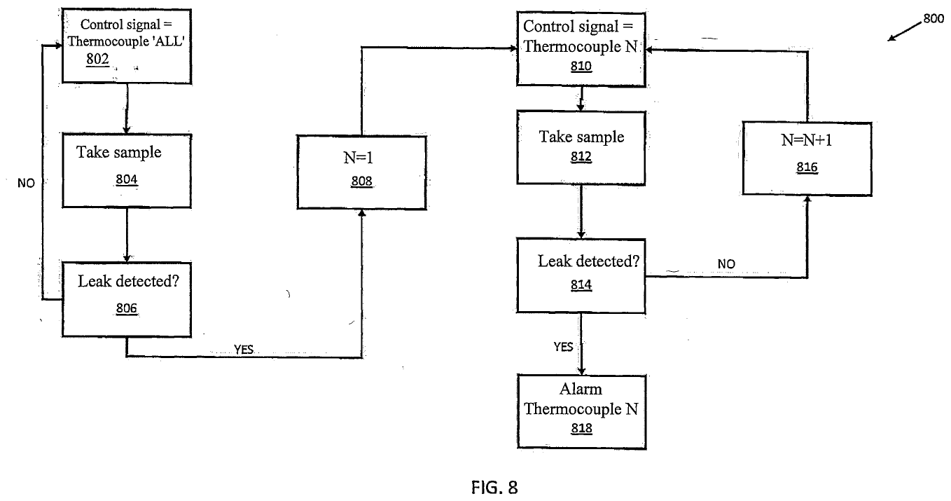

FIG. 8 is a flowchart depicting a method 800 of leak detection that may be implemented by system 700 of FIG. 7 in which manifold 710 allows selective sampling of air from all or individual thermocouples 702. Method 800 may be implemented by a control system implemented within detector 712, for example. In other embodiments, method 800 may be implemented by a separate control system or computer 718 that is connected to and in communication with manifold 710. Method 800 is implemented on a chamber having a number of thermocouples equal to ‘N’.

In step 802, a control signal is generated and transmitted (e.g., by detector 712 or computer 718) to manifold 710 causing manifold 710 to connect all sample hoses 706 for all thermocouples 702 to main hose 714 allowing detector 712 to sample air from all thermocouples 702 simultaneously.

In step 804, with manifold 710 properly configured, detector 712 samples air from all thermocouples 702 simultaneously. This step may involve detector 712 applying a vacuum for a period of time sufficient to clear old air out of the sample hoses connected between detector 712 and the thermocouples 702 before performing any analysis of the sampled air. In step 806 detector 712 determines whether a leak has been detected (e.g., a concentration of hydrogen in the sampled air exceeds a predetermined threshold). If not, and no leak has been detected, the method returns to step 802 to enter a monitoring loop in which air from all thermocouples 702 is monitored either continuously or at time intervals to detect a leak.

If, however, in step 806, detector 712 determines that a leak has been detected, method 800 enters a second control loop in which the specific thermocouple 702 with the leak is identified. Specifically, in step 808 a counter N is initialized to a value of ‘1’ to identify the chamber's first thermocouple 702. In step 810, a control signal is generated and transmitted (e.g., by detector 712 or computer 718) to manifold 710 causing manifold 710 to connect the sample hose 706 associated with thermocouple 702 ‘N’ to main hose 714 allowing detector 712 to sample air from that specific thermocouple 702. In step 812, detector 712 samples air from that specific thermocouple 702. This step may involve detector 712 applying a vacuum for a period of time sufficient to clear old air out of the sample hoses connected between detector 712 and the thermocouple 702 before performing any analysis of the sampled air. In step 814, detector 712 determines whether a leak has been detected (e.g., a concentration of hydrogen in the sampled air exceeds a predetermined threshold). If not, and no leak has been detected, the method moves to step 816 in which the counter ‘N’ is incremented. Steps 810, 812, and 814 are then repeated and applied to the thermocouple 702 identified by the incremented value of N. In this manner, method 800 iterates through all N thermocouples 702 to identify a thermocouple 702 with a breach.

If, however, in step 814 a leak is detected, the method moves to step 818 in which an alarm signal is generated that identifies the specific thermocouple 702 in which the leak was detected (i.e., the thermocouple 702 identified by the current value of the counter ‘N’).

In some embodiments, the configuration of manifold 710 may not be reconfigurable automatically. Instead, manifold 710 may be configured to allow manual reconfiguration enabling sampling of all thermocouples 702 simultaneously or of a specific thermocouple 702 or combination of thermocouples 702. In that case, a technician my operate manifold 710 manually to substantially implement method 800. A manually operated manifold 710 may be preferably in some installations of system 700 in which it may be difficult to route electrical power and appropriate control signals to manifold 710 and in which manual operation of manifold 710 is a feasible solution.

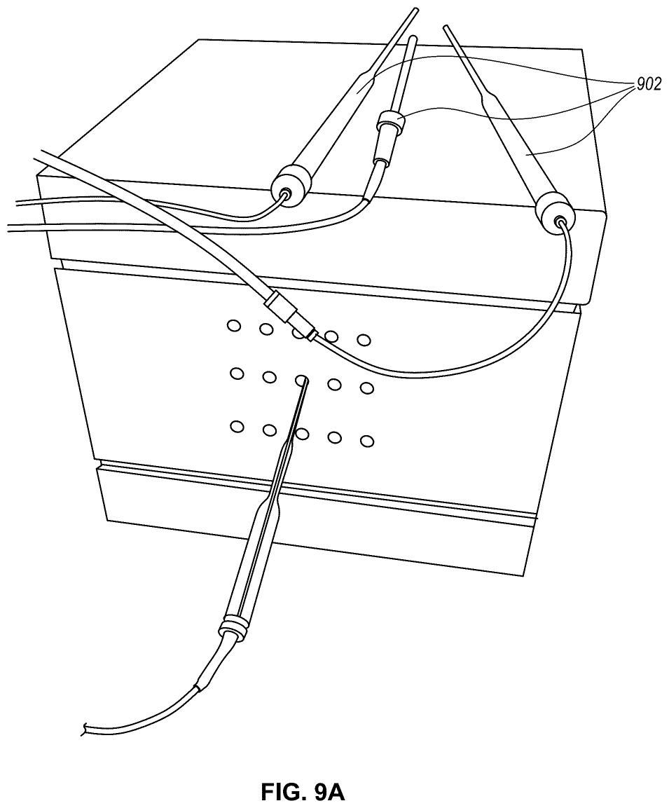

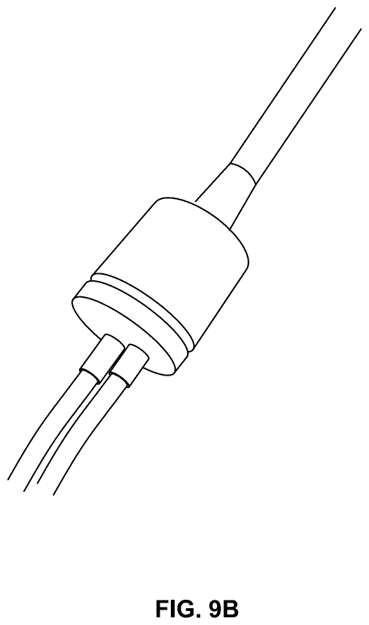

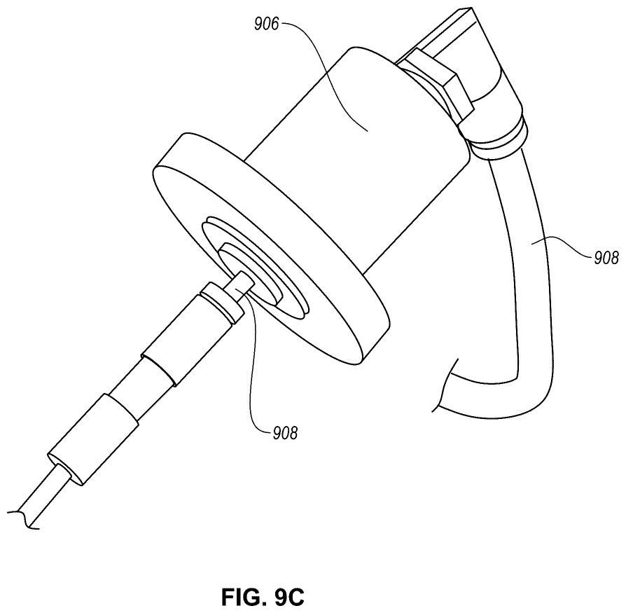

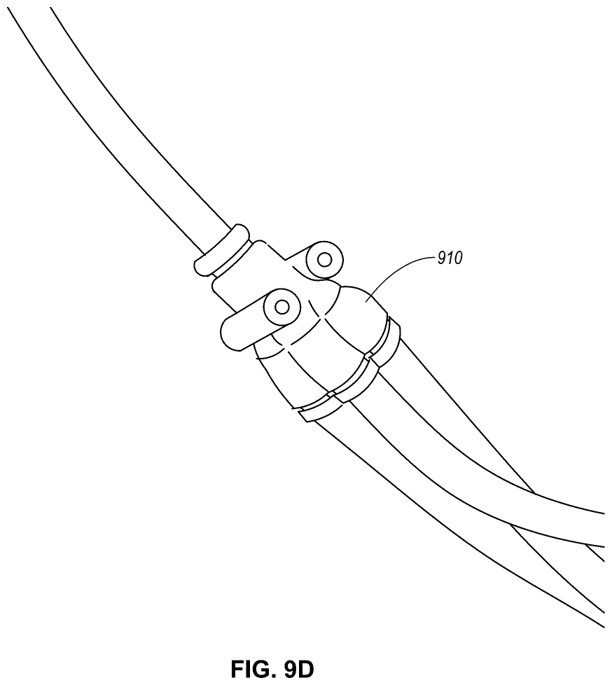

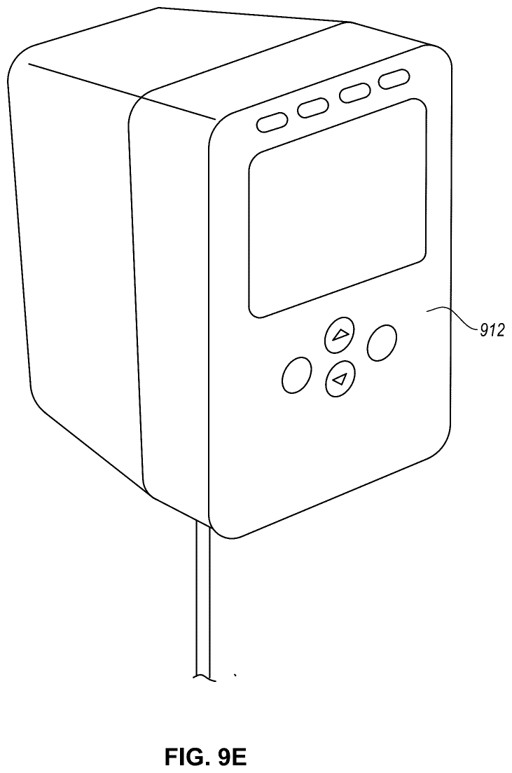

FIGS. 9A-9E are images depicting components of a leak detection system configured to implement functionality of system 700 and as described herein. FIG. 9A depicts a plurality of thermocouples 902 (e.g., thermocouples 308, 310, 702). FIG. 9B depicts a thermocouple and end cap (e.g., end caps 318 and 358 of FIG. 3) thereof. FIG. 9C depicts rotating hub 906 (e.g., rotating hub assembly 364, FIG. 3) coupled to sections of sample hose 908. FIG. 9D depicts manifold 910 (e.g., manifold 710) coupled to collections of sample hoses. FIG. 9E depicts a detector 912 (e.g., detector 712).

Embodiments of the present leak detection system and method are described in conjunction with the specific application of leak detection (and thereby breach detection) in reaction chamber thermocouples. It should be understood, however, that the present system could be utilized to perform leak detection in non-thermocouple type devices. In fact, the present leak detection system could be implemented in conjunction with any types of devices that comprise housings that penetrate into an interior volume of a reaction chamber. As such, the present system could be utilized to perform leak detection for the housings of devices such as cameras, sensors, laser systems, or other types of devices that are mounted into a reaction chamber in housings.

The inventions and methods described herein can be viewed as a whole, or as a number of separate inventions, that can be used independently or mixed and matched as desired. All inventions, steps, processed, devices, and methods described herein can be mixed and matched as desired. All previously described features, functions, or inventions described herein or by reference may be mixed and matched as desired.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A system, comprising:
a chamber configured to receive a semiconductor wafer;
a first thermocouple coupled to the chamber and wherein at least a portion of the first thermocouple is disposed within an interior volume of the chamber;
a first sample hose in fluid communication with an interior volume of the first thermocouple; and
a detector in fluid communication with the first sample hose, the detector being configured to analyze a gas received from the first sample hose.

2. The system of claim 1, wherein the first thermocouple includes an end cap including a first channel and a second channel, wherein a first thermocouple wire of the first thermocouple extends through the first channel of the end cap and the first sample hose is coupled to the second channel.

3. The system of claim 2, wherein the second channel in the end cap includes a first segment extending in parallel to the first channel and the second channel in the end cap includes a second segment extending radially away from a central axis of the end cap.

4. The system of claim 1, further comprising:
a second thermocouple coupled to the chamber and wherein at least a portion of the second thermocouple is disposed within the interior volume of the chamber; and
a second sample hose in fluid communication with an interior volume of the second thermocouple, wherein the detector is in fluid communication with the second sample hose.

5. The system of claim 1, wherein the detector is configured to analyze the gas to determine whether a concentration of hydrogen in the gas exceeds a predetermined threshold and, when the concentration of hydrogen exceeds the predetermined threshold, generate an alarm signal.

6. A system, comprising:
a plurality of sample hoses;
a manifold including an output port and a plurality of input ports, wherein each input port of the plurality of input ports is configured to couple to a first end of a sample hose of the plurality of sample hoses wherein, wherein second ends of each sample hose in the plurality of sample hoses are configured to couple to an interior volume of a thermocouple housing of a plurality of thermocouple housings; and
an output hose connected between the output port of the manifold and a detector, wherein the detector is configured to detect leaks in thermocouple housings of the plurality of thermocouple housings by analyzing a content of a gas retrieved from the output hose.

7. The system of claim 6, wherein the manifold is configured to selectively connect a single sample hose of the plurality of sample hoses to the output port of the manifold.

8. The system of claim 7, wherein a controller is coupled to the manifold and the controller is configured to cause the manifold to sequentially connect individual sample hoses of the plurality of sample hoses to the output port of the manifold to enable the detector to detect a leak in a specific thermocouple housing coupled to one of the plurality of sample hoses.

9. The system of claim 6, wherein the detector is configured to analyze the gas to determine whether a concentration of hydrogen in the gas exceed a predetermined threshold and, when the concentration of hydrogen exceeds the predetermined threshold, generate an alarm signal.

10. A system, comprising:
a first sample hose configured to couple to a thermocouple housing to place the first sample hose in fluid communication with an interior volume of the thermocouple housing, wherein the thermocouple housing is configured to couple to a reaction chamber and a connection between the thermocouple and the reaction chamber allows the thermocouple to rotate with respect to the reaction chamber;
a rotating hub including a first connection port and a second connection port, wherein the first connection port is configured to connect to the first sample hose;
a second sample hose configured to connect to the second connection port of the rotating hub, wherein when the first connection rotating hub is connected to the first sample hose and the second connection port is connected to the second sample hose, the second sample hose is in fluid communication with the first sample hose and the rotating hub is configured to enable the second sample hose to rotate with respect to the first sample hose; and
a detector in fluid communication with the second sample hose, the detector being configured to analyze gas received from the interior volume of the thermocouple housing to detect a leak in the thermocouple housing.

11. The system of claim 10, wherein the detector is configured to analyze the gas to determine whether a concentration of hydrogen in the gas exceed a predetermined threshold and, when the concentration of hydrogen exceeds the predetermined threshold, generate an alarm signal.

12. The system of claim 10, further comprising a manifold including an output port and a plurality of input ports, wherein a first input port of the plurality of input ports is configured to connect to the second sample hose and the output port is configured to connect to the detector.

13. The system of claim 12, further comprising a third sample hose configured to couple to a device housing to place the third sample hose in fluid communication with an interior volume of the device housing, wherein the device housing is configured to couple to the reaction chamber and the third sample hose is configured to connect to a second input port of the plurality of input ports of the manifold.

14. The system of claim 13, wherein the detector is configured to analyze gas received from the interior volume of the device housing to detect a leak in the device housing.

15. The system of claim 13, wherein the manifold is configured to selectively connect the second sample hose or the third sample hose to the output port of the manifold.

16. The system of claim 15, wherein a controller is coupled to the manifold and the controller is configured to cause the manifold to sequentially connect the second sample hose and the third sample hose to the output port of the manifold to enable the detector to detect a leak in either the thermocouple housing or the device housing.

17. The system of claim 13, wherein the device housing includes at least one of a second thermocouple housing, a camera housing, and a sensor housing.

18. The system of claim 10, further comprising an end cap configured to couple to an end of the thermocouple housing, wherein the end cap includes a first channel and a second channel, wherein the first channel is configured to receive a thermocouple wire of a thermocouple disposed within the thermocouple housing and the first sample hose is in fluid communication with the second channel.

19. The system of claim 18, wherein the second channel in the end cap includes a first segment extending in a first direction that is parallel to the first channel and the second channel in the end cap includes a second segment extending radially away from a central axis of the end cap.

20. The system of claim 19, wherein the second segment is in fluid communication with the interior volume of the thermocouple housing when the end cap is coupled to the end of the thermocouple housing.
